(19) United States
(12) Patent Application Publication
(10) Pub. No.: US 2012/0196225 A1
(43) Pub. Date: Aug. 2, 2012

(54) Photo Patternable Coating Compositions of Silicones and Organic-Inorganic Hybrids

(75) Inventor: CHENGHONG LI, BOXBOROUGH, MA (US)

(73) Assignee: NAMITEK SPECIALTY MATERIALS CORP., BOXBOROUGH, MA (US)

(21) Appl. No.: 13/014,818

(22) Filed: Jan. 27, 2011

(51) Int. Cl. G03F 7/004

(52) U.S. Cl. 430/270.1

(57) ABSTRACT

A negative-tone photo patternable coating composition containing: (1) at least one silicone or organic-inorganic hybrid resin with acid labile alkoxysilane groups which can be thermally decomposed into silanol groups at 80-160° C. in the presence of a catalytic amount of strong acid; (2) optionally, an organic/polymer with two or more trialkoxysilyl, alkyldialkoxysilyl, or dialkylalkoxysilyl functional groups; (3) a photoacid generator; (4) an acid quencher; (5) a flow control agent; and (6) at least one organic solvent. Methods of preparing the silicones and/or organic-inorganic hybrids and procedures of processing the photo patternable compositions are described.

### FIELD OF THE INVENTION

This invention is related to imagable coating compositions of silicones or organic-inorganic hybrids. These compositions can be spin-casted on substrates such as wafers of silicon, silicon arsenide, or quartz as films and directly imaged or patterned using electronic-magnetic radiations or electron beams and a photomask. After developing using a liquid such as organic solvents or mixtures, a negative image or pattern of the photomask is generated on the exposed silicone or organic-inorganic hybrid layer.

### BACKGROUND OF THE INVENTION

The term “silicone”, by definition, represents polymers of a class of naturally nonexistent chemicals defined as [R₁Si(═O)R₂], where R₁ and R₂ are organic radicals such as methyl, ethyl, propyl, etc. However, the definition of this term has been more or less extended to all siloxane condensation copolyemrs of triorganosilanol, diorganosilanediol, organosilanetriol, and orthosilic acid, which are often unstable intermediates derived from hydrolysis of corresponding organoalkyoxysilanes (Rₙ(R′O)₄₋ₙSi), organohalogensilanes (RₙX₄₋ₙSi), or organocarboxysilanes (Rₙ(R″COO)₄₋ₙSi, where n is an integer of 0-3. These silicones or polysiloxane polymers may be also viewed as silica glass with portions of Si—O— bonds replaced by mono functional radicals such as methyl, ethyl, phenyl groups, etc. If two or more Si—O— bonds are replaced by di- or multi-functional organic radicals, then these resulting polymers become three-dimensional networks of Si—O—Si and organics. These types of polymers are often referred to as organic-inorganic hybrids in recent literature, however, “organic-inorganic hybrid” is a more general term, it also includes hybrid networks of ME-O-ME and organics, where ME represents a metal or semi-metal atom such as Ti, Zr, Ge, Ga, etc. Handbook of Organic-Inorganic Hybrid Materials and Nanocomposites edited by Hari Singh Nalwa [American Scientific Publications, January 2003] is a major reference work that provides coverage on various emerging aspects of these types of materials.

Silicone or organic-inorganic hybrid coating compositions are typically obtained by sol-gel processes through hydrolysis and condensation of various types of alkoxysilanes (Rₙ(R′O)₄₋ₙSi) or metal alkoxides (Rₙ(R′O)₄₋ₙME, Me=metal or semi-metal), together with organics having multiple (R′O)₃₋ₓRₓSi— radicals, where x is an integer of 0-2. Depending on the number of (R′O)₃₋ₓRₓSi— radicals the organic carries, the resulting chemical may be referred to as bridged silanes or star silanes. Organic-inorganic hybrids can be also prepared by reactions of nanoparticles or organic functional nanoparticles of metal oxides with organic resins.

Silicones or organic-inorganic hybrids may be used as sacrificial or non-sacrificial layers in integrated circuits (IC), micro/nano electronic mechanical systems (MEMS/NEMS), microfluidics, integrated optical devices, etc. For more information about possible applications of these new types of materials please refer to The Supermolecular Chemistry of Organic-Inorganic Hybrid Materials edited by Knut Rurack and Ramon Martinez-Manez [Wiley, March 2010].

To make micro or nano scale features, it is generally required that these silicone or hybrid layers be patterned using photoresist and photolithography. A photoresist is a specially formulated coating composition which can be spun/roll-coated on top of underlying layer to be patterned. Upon exposure with an image-wise radiation (e.g. electromagnetic waves or electron/ion beams) obtained by passing a radiation through a mask carrying the required pattern, the exposed areas of the coating undergo significant physical or chemical changes so that its solubility in a developer is considerably different from the unexposed area. So after development, the pattern of the mask is replicated (positive tone) or inversely replicated (negative tone) on the photoresist layer. Subsequently, the patterned photoresist layer is used as a mask to dry or wet-etch the underlying layer, and eventually the photoresist pattern is transferred to the underlying layer.

Photoresists can be divided into negative tone and positive tone. When a negative tone photoresist is exposed, the coating becomes much less soluble in the developer due to solubility changes related to polarity changes or crosslinking induced by photo chemical reactions. Therefore, an inverted image of the photomask pattern is generated if negative tone photoresist is used. For positive tone photoresist, it is just the opposite; the exposed resist becomes much more soluble in the developer because of chain scission, polarity changes, or production of acids. Thus, when a positive tone photoresist is used, the photomask pattern is directly duplicated in the photoresist layer. Negative tone and positive tone photoresist compositions and their uses are well known to those skilled in the art.

Photoresists have been used for decades to pattern surfaces of bulk or film materials in micro- or nanofabrication. This technology generally involves preparation of a stack of thin layers of different materials (e.g. anti-reflection coating, photoresist, etc.) and utilization of multiple processing steps (e.g. resist exposure, post-exposure treatment, resist development, wet or dry etch, and resist stripping, see FIG. 1a). Residual resist is often stripped by thermal oxidation or oxygen dry etch; however, during this process it is quite likely that the required patterns be damaged. An obvious solution to avoid this potential problem is to use self-patternable layer because the stripping process is not necessary in this case. Of course, the use of self patternable layer can also significantly simplify the patterning process [FIG. 1b]. Unfortunately, self-patternable compositions are generally not available for most materials. It is often very difficult, if not impossible, to formulate high performance self-patternable compositions for many materials. Photosensitive polyimides and color resists are two of the few successful examples of self patternable compositions: the former are well accepted for IC packaging applications, while the color resists are widely used for manufacturing LED flat panel display.

Silicone or silicon containing layers have extraordinary etch resistance to oxygen plasma. In the past decades, numerous attempts have been made to develop silicon-containing photoresists (BILAYER resist) or processing techniques to introduce silanes to either exposed or non-exposed photoresist zones (Si-CARL or Top-CARL) so that the resist pattern obtained can take advantages of etch resistance of the silicon moieties. The TRILAYER process is another technology which utilizes the excellent etch resistance of silicone coatings to oxygen plasma. In this process, the silicone layer is introduced as an intermediate sacrificial layer (serve as anti-reflection coating as well as hardmask) on top of a thick carbon-rich underlayer, and on top of the silicone layer is a thin layer of general purpose photoresist. The photoresist is first patterned as usual, then a halogen plasma dry etch process is used to transfer the pattern from the photoresist to the silicone intermediate layer. Subsequently, the silicone layer is used as a mask and oxygen plasma etch is used to etch the underlayer. The TRILAYER process makes it possible to use a thin photoresist layer to process a thick carbon rich layer and generate patterns with very high aspect ratios.

A few silicon containing photoresists are commercially available, although their applications so far have been limited. Hydridosilsesquioxanes from Dow Corning under Trade Designation of FOX, for example, is a high resolution EUV/X-Ray/E-beam resist which was reported to be capable of producing 22 nm wide lines.

Photo sensitivity of silicone or silicone containing polymers is mainly realized through reactive organic side groups such as epoxy, acryloxy or methacryloxy groups, vinyl ether, etc., which can be polymerized via irradiation induced free radical polymerization or cationic polymerization. These reactions lead to a highly crosslinked network, and hence result in negative tone photoresists. Photoacid promoted crosslinking of hydroxyl functional silicones are also reported to be used in some negative tone photoresists.

Another approach is to use labile alkoxy groups such as t-butoxy. These alkoxy groups are stable up to about 350° C., however, decompose at much lower temperature (100-200° C.) to form silanols and gas (e.g. butene or pentene, etc.) in the presence of an acid catalyst. The system can be made photo patternable when a photo acid generator is used instead of the acid catalyst. This approach is reflected in “glass resist” in U.S. Pat. No. 5,393,641 invented by Toshio Ito and Miwa Sakata (assigned to Oki Electric Industry Co., Ltd.). The “glass resist” is somehow similar to the chemically amplified photoresists (CAMP) used in 248 nm or 193 nm photolithography: both involve thermal cracking of esters to form acids (silanols vs phenols/carboxylic acids) in the presence of a catalytic amount of a strong acid catalyst. The differences are that with the glass resist, the resulting silanols are much weaker acids than phenols or carboxylic acids (in normal photoresists); unlike phenols or carboxylic acids, silanols can easily self-condense to form siloxane linkages, leading to a crosslinked system. Thus, unlike CAMP photoresists, the glass resist is negative-tone rather than positive-tone.

### BRIEF SUMMARY OF THE INVENTION

The current invention discloses negative-tone photo patternable coating compositions consist of a major component of silicones or organic-inorganic hybrids resins with acid labile alkoxysilane groups [e.g. Si—O-t-Butyl, Si—O-t-Pentoxy, etc.], and optionally, one or more components of organics/polymers with multi-trialkoxysilyl groups. These major components are transparent at the work wavelength of photolithography. The component with acid labile alkoxysilyl groups is stable up to 300-400° C. without catalyst but decomposes at 80-200° C. in the presence of a catalytic amount of strong acid to form volatile gases and silanol groups. The resulting silanol groups then self-condense to form siloxane linkages and water or condense with alkoxysilane groups to form siloxane linkages and alcohol. To make the composition irradiation sensitive, a photo acid generator (PAG), although in a very small quantity, is an indispensible in the composition. Other components include but not limited to acid quenchers or scavengers, flow control agents, and organic solvents. These compositions can be spun-cast on wafers of silicon, quartz, silicon arsenide, silicon nitride, etc. to form perfect films. Upon exposure using a photomask, these films can be patterned and utilized as sacrificial or non-sacrificial layers for manufacturing integrated circuits, micro/nano electromechanical systems, or microfluidics, etc.

### BRIEF DESCRIPTION OF THE FIGURES

FIG. 1 demonstrates the process differences when fabricating micro- or nano-patterns of (1) non-patternable or (2) patternable silicones or organic-inorganic hybrid layers.

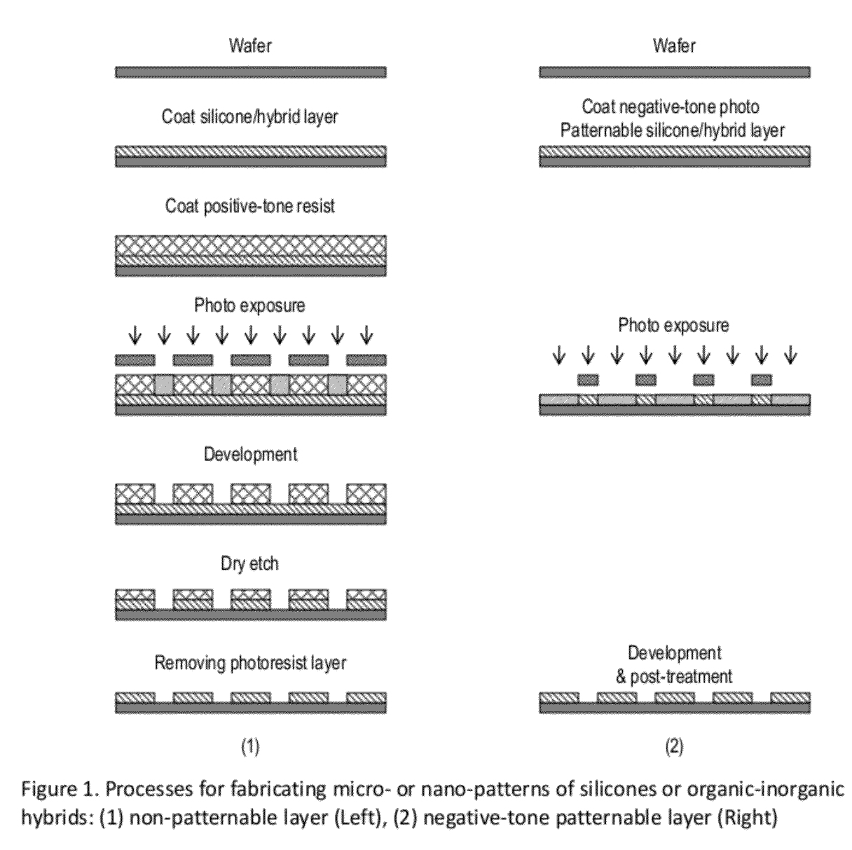

FIG. 2 shows a soluble organic-inorganic hybrid polymer, which upon UV radiation, and in the presence of a trace amount of photoacid generator, thermally decomposes to form silanols and eliminates butene, followed by silanol condensation, and forming a three-dimensional hybrid network. This is the basic foundation of the negative-tone photosensitivity of the silicones or organic-inorganic hybrid compositions of the current invention.

### DETAILED DESCRIPTION OF THE INVENTION

The negative-tone photo patternable coating compositions disclosed in the present invention is comprised of a resin of silicone or organic-inorganic hybrid with acid labile alkoxy groups which is transparent at the work wavelength of photolithography. Structurally, this type of resin is composed of macromolecules, which are formed by linking a set of silicon tetrahedrons described by Structure (1) via siloxane bond (Si—O—Si) or organics/polymer chains in a linear, branched, polycyclic, polyhedral, or mixed manner.

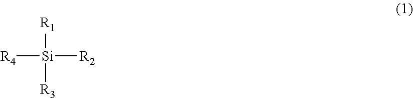

where R₁, R₂, R₃ and R₄ are mono or multi-radicals selected from the following five categories of radicals (Rₐ, R_{b}, R_{c}, R_{d}, and Rₑ).
where

Rₐ, R_{b}, R_{c}, R_{d}, and Rₑ are radicals containing no basic functional groups (pK_{b}<12) so photoacid generated won't be neutralized. Therefore, radicals containing basic groups such as amine, pyridine, imine, guanidine, etc. much be excluded from the lists of Rₐ, R_{b}, R_{c}, R_{d}, and Rₑ.

Rₐ: mono alkyl (hydrogen, alkyl, aryl, aralkyl) radical with 0-12 carbons, however, 1-6 carbons preferred. It is a pendant group not linking to other silicon tetrahedrons. It can be linear, branched, or cyclic/polycyclic in structure. Examples are methyl, ethyl, propyl, 2-propyl, n-butyl, 2-butyl, t-butyl, phenyl, o, m, p-methylphenyl, etc. Oxygen, nitrogen, sulfur, or phosphor atoms may be included in a mono radical R group, but basic groups must be excluded. Examples of proper Rₐs are 2-cyanopropyl, 3-cyanopropyl, 3-methoxypropyl, 3-(methoxycarbonyl)ethyl, 3-mercaptanpropyl, etc.

R_{b}: organic diradical or multi-radical, which are linked to two or more silicon tetrahedrons. Again R_{b} may be selected from hydrocarbons or organics containing oxygen, nitrogen, sulfur, or phosphor atoms, but those with basic groups should not exclude. A simple di-radical R_{b} group can be, but not limited to —[CH₂]ₙ—, n=1-100, 1,4-phenylene, 1,3-phenylene, 1,2-phenylene, 1,4-cyclohexylene, 1,3-cyclohexylene, 1,2-cyclohexylene, polyethyl glycols, or Polypropylene glycols. A simple multi-radical R group can be, but not limited to 1,3,5-Ph≡, 1,2,4-Ph≡, 1,2,3-Ph≡, —CH₂CH(−)CH₂—, ═C═CHCH₂—, etc.

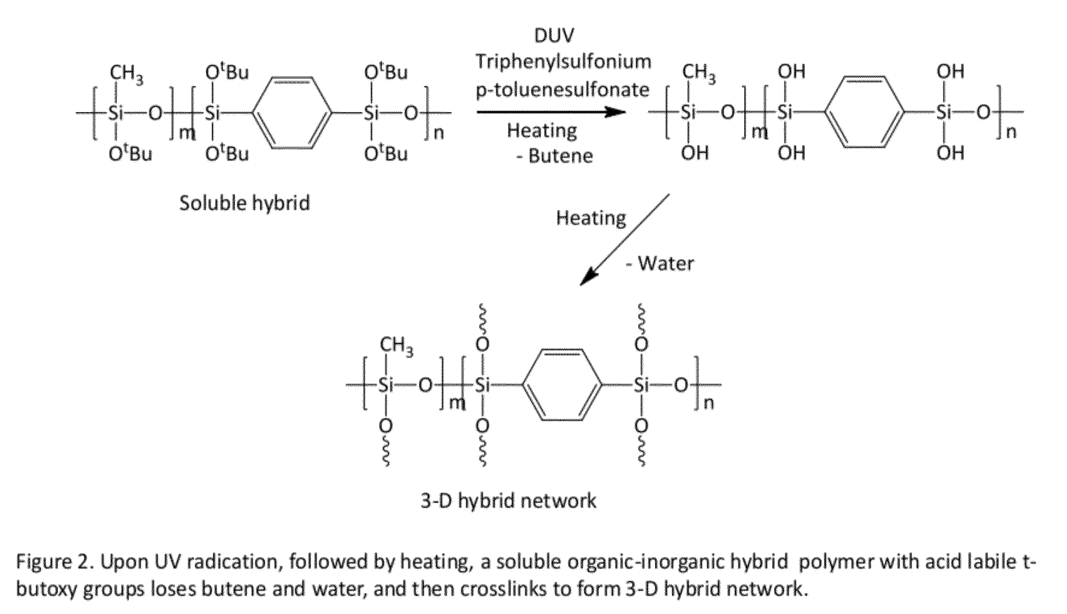

R_{c}: -OL group, an acid labile alkoxy group. As defined earlier, the acid labile groups (Si-OL) is stable up to 300-400° C. without catalyst but decomposes at 80-200° C. in the presence of a catalytic amount of strong acid to form volatile gases and silanol groups. OL can be selected from databases of acid labile groups used for DUV or 193 nm photoresist technologies well known to those skilled in the art. It includes but not limited to t-butoxy, t-pentoxy (2-methyl-2-butoxy), 1-phenyl-1-ethoxy, 2-phenyl-2-propoxy, and similar species; Due to its small volume, t-butoxy group is the most preferred if a dense film/pattern is essential. Other acid labile groups such as silyl acetals or ketals (represented by Si—OCRR′—OR) may be principally used, but less preferred because of their large mass and poorer stability. These acetal/ketal species can be fragmented, in the presence of strong acid catalyst and moisture, to form silanol groups, volatile aldehydes or ketones, and alcohols [FIG. 2]. The polarity changes resulted from silanol formation, together with subsequent silanol condensation form the foundation for the negative-tone nature of coating compositions in the present invention.

R_{d}: —OR group, where R is a mono radical similar to Rₐ. Unlike R_{c}, R_{d} is not acid labile (typically hydrogen, methyl, ethyl, or propyl, isopropyl). These groups are nonessential to the current invention, their presence are mostly due to incomplete hydrolysis or silanol condensation, and

Rₑ: —OSi group, which represents a siloxane linkage (Si—O—Si).

For the silicon tetrahedron unit to be part of a resin backbone, R₁, R₂, R₃ and R₄ in Structure (1) must contain at least one R_{b} or Rₑ. R₁, R₂, R₃ and R₄ may contain 0-2 Rₐ s (typically 0 or 1), and 0-3 R_{c}s (statistically 0.25-3, preferably 0.5-2).

As photo patternable compositions, further limitations to Rₐ, R_{b}, R_{c}, R_{d}, and Rₑ are required so that the resin of silicone or organic-inorganic hybrid is transparent at the work wavelength of photolithography (typical lithography wavelengths are 365 nm, 248 nm, and 193 nm). Therefore, Rₐ, R_{b}, R_{c}, R_{d}, and Rₑ cannot include any fused aromatic radicals due to the high absorption. For 193 nm photolithography, even benzene ring must be excluded in Rₐ, R_{b}, R_{c}, R_{d}, and Rₑ due to its high absorption.

According to the description above, the polymer network of the silicone and/or organic-inorganic hybrids may be further elucidated by the following structure.

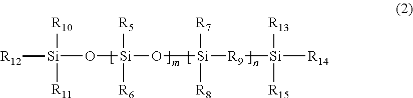

where
1) m and n are numbers of duplication (m and n not zero at the same time).
2) R₅, R₆, R₇, R₈, and R₉ in each duplication unit are not necessary the same.
3) R₅ and R₆ are selected from Rₐ, R_{b}, R_{c}, R_{d}, and Rₑ. If R₅ and R₆ are selected from Rₐ, R_{c}, and R_{d} only, the silicon tetrahedral unit is a chain extension unit. If either or both of R₅ and R₆ are R_{b} or Rₑ, the silicon tetrahedral unit is a network joint.
4) R₇ and R₈ are selected from Rₐ, R_{b}, R_{c}, R_{d}, and Rₑ, and R₉ is a R_{b}. If R₇ and R₈ are Rₐ, R_{b}, and R_{d}, and R₉ is a diradical R_{b}, the silicon tetrahedral unit is a chain extension unit. Otherwise, the silicon tetrahedral unit is a network joint.
5) R₁₀, R₁₁, R₁₂, R₁₃, R₁₄, R₁₅ are selected from Rₐ, R_{c}, R_{d}, the silicon tetrahedrons they attached to are pendant groups.
6) The number of network joints of the polymer is limited so that the silicone or organic-inorganic hybrid resin remain soluble.
7) A large percentage (10-100%, 25-75% preferred) of R₅-R₈ and R₁₀-R₁₅ must be R_{c} (-OL), the acid labile alkoxy group.

The silicone or organic-inorganic hybrid resins containing the acid labile alkoxy (OL) can be prepared by condensation polymerization of monomers containing these alkoxy groups. For example, di-t-butoxy-diacetoxysilane, methyl-t-butoxy-diacetoxysilane, vinyl-t-butoxy-diacetoxysilane, etc. Many of such silanes can be prepared from corresponding chlorosilanes or acetoxysilanes by alcoholysis using tertiary alcohols. Silicones or organic-inorganic reactions of the current invention are prepared by the well-known sol-gel reactions. However, it is also possible to prepare those resins by reacting chlorosilanes or acetoxysilanes with metal oxides, bicarbonate, or carbonates (e.g. ZnO, NaHCO₃, Na₂CO₃, etc.). Among them, ammonium carbonate or bicarbonate is most preferred because the reaction products are ammonium salts, carbon dioxide, and siloxanes. During the process, the hydrochloric acid or acetic acid generated is neutralized without introducing metal impurities. In IC industries, metal ion contents are under very strict control. Ester exchange between common alkoxysilanes such as methoxysilane or ethoxysilane and tertiary alcohols provides another feasible method to make silanes or polymers with acid labile groups. Hydrolysis and polycondensation of low alkoxysilanes such as methoxysilanes and ethoxysilanes can also introduce a limited amount of tertiary alkoxy groups. In addition, modification of siloxane polymers (e.g. hydridosiloxane reacting with t-butanol) may also be another feasible but more expensive way to introduce acid labile alkoxy groups.

Resins described by Structure (1) may be prepared by co-hydrolyzing the following one or more types of silanes specified by (A), (B), and (C).

(A) Monomeric silanes Specified by SiRₘXₙ(OL)₄₋ₘ₋ₙ
Where
   1. R is a mono radical defined earlier as Rₐ in the present invention,
   2. OL is an acid labile group defined earlier as R_{c},
   3. X is a better leaving group than OL group (e.g. halogen, carboxylate, methyl, ethyl, etc.),
   4. m+n are integers of 1-3, and m+n≦3,
   5. Non-limiting examples including Si(Ot-Bu)₂(OAc)₂, Si(Ot-Bu)₃(OH), Si(Ot-Bu)₂(OCH₃)₂, Si(Ot-Bu)₂Cl₂, Si(CH₃)(t-Bu)(OAc)₂, Si(CH═CH₂)(Ot-Bu)(OAc)₂, etc.

Not all the silanes listed above are available commercially, however, they can be easily obtained from related acetoxysilane or silane halides by reacting with related tertiary alcohol, for example, Si(CH₃)(t-Bu)(OAc)₂ from Si(CH₃)(OAc)₃ and Si(CH═CH₂)(Ot-Bu)(OAc)₂ from Si(CH═CH₂)(OAc)₃

(B) Bridged silanes specified by (OL)_{4-m′-n′}X_{n′}R_{m′}Si—R′—SiSiRₘXₙ(OL)^{4-m-n}
Where
   1. R is a mono radical defined earlier as Rₐ,
   2. OL is an acid labile group defined earlier as R_{c}
   3. X is a better leaving group than OL group (e.g. halogen, carboxylate, methyl, ethyl, etc.),
   4. m, m′, n, n′ are integers of 1-3, and m+n≦3, m′+n′≦3
   5. R′ is a di-radical group defined earlier as R_{b}. It may contain carbon, oxygen, nitrogen, phosphor, or other atoms as long as its pK_{b} is greater than 12.
6. It is preferred that (n+n′)/2 be between 1.8 and 2.2 so that the system does not gel during the hydrolysis and condensation stage.

Non-limiting examples of R′ include direct bond (i.e. a disilane); —(CH₂)ₙ—, n=1-10; —C≡C— (acetylene); —CH₂═CH₂— (ethylene); 1,4,1,3,1,2-C₆H₄— (benzene); —C₆H₄—O—C₆H₄—; —CH₂═CH—CH═CH₂— (butadiene); 1,4-, 1,3-, or 1,2-C₆H₁₀-(cyclohexylene); 1,4-, 1,3-, or 1,2-CH₂CH₂C₆H₄—CH₂CH₂—; 1,4-, 1,3-, or 1,2-CH₂C₆H₄—CH₂—, etc.

Many of those bridged chlorosilanes, methoxysilanes or ethoxysilanes are commercially available. The bridged silanes can be prepared from these compounds by reacting with tertiary alcohols through alcoholysis or ester exchange.

(C) Star silanes specified by R′(SiRₘXₙ(OL)₃₋ₘ₋ₙ)ₖ
Where
   1. R is a mono radical defined earlier as Rₐ,
   2. R′ is a multi-radical defined earlier as R_{b},
   3. OL is an acid labile group defined earlier as R_{c},
   4. X is a better leaving group than OL group (e.g. halogen, carboxylate, methyl, ethyl, etc.),
   5. m and n are defined as the average number of R and X groups per silicon atom, and k is the number of arms on the star structure,
   6. m and n are numbers between 0-3 (not necessary integer) and m+n<3.

Non-limiting examples of R′ include

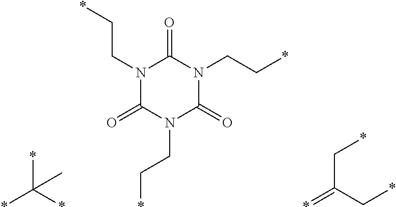

where a * indicates the carbon to which a silyl group is attached.

A star silane may have as many functional groups as three times the number of arms. To avoid forming a gel, the average of n should be controlled to around 2/3k (2.2 for a tri-star, 1.67 for a quaternary-star). These materials can be prepared from related chlorosilanes, methhoxysilanes, or ethoxysilanes through either alcoholysis or ester exchange. Another approach is to use polychlorinated organic, alkyllithium, and chlorosilanes, which is not described in the present invention.

The average molecular weight of the resin of silicone or organic-inorganic hybrid can range from 1,000-100,000, but as photo patternable coating compositions, the preferred molecular weight is 2,000-10,000, even more preferred is 2,000-8,000, so the resin is soluble enough in organic developers.

Optionally, photo patternable coating compositions of silicones and organic-inorganic hybrids may also be formulated using a simple silicone or organic-inorganic hybrid resin containing acid labile groups together with one or more organics/polymers with multi-alkoxysilyl groups. A simple silicone containing acid labile group is poly(di-t-butoxysiloxane) or poly(methyl-t-butoxysiloxane). The organics/polymers with multi-alkoxysilyl groups can be bridged alkoxysilanes defined by (RO)₃₋ₘR′_{m′}Si—R″—SiR′ₘ(OR)₃₋ₘ or star alkoxysilanes defined as R″(SiR′ₘ(OR)₃₋ₘ)ₖ, where OR, R′, and R″ are defined earlier as normal alkoxy radical (R_{d}), mono radical (Rₐ), and di- or multi-radicals (R_{b}), respectively. In these formulations, photo acid can crack the acid labile groups to generate silanol groups, which then undergo either self condensation or silanol-alkoxysilane (Si—OR) condensation to crosslink the system. It is preferred that the mole ratio of OL to OR be in the range of 0-1, more preferably 0-0.6, so that the system can be sufficiently crosslinked. Examples of commercial bridged alkoxysilanes and star alkoxysilanes include, but not limit to 1,4-bis(triethoxysilyl)benzene, 4,4′-bis(triethoxysily)biphenyl, 1,2-bis(triethoxysilyl)ethane, bis(triethoxysilylethyl)vinylmethylsilane, 1,3-bis(triethoxysilylethyl)tetramethyldisiloxane, bis(triethoxysilylpropoxy)polypropylene oxide, 1,1,2-tri(triethoxysily)ethane, tris(trimethoxysilyl)isocyanurate, etc.

The photo acid generators may be onium salts, sulfonate compounds, nitrobenzyl esters, triazines, sulfonate esters of hydroxyimides, etc. Commonly used photo acid generators for the current invention include sulfonate (e.g. camphorsulfonate, 4-toluenesulfonate, benzenesulfonate, etc.) and super acid (e.g. trifluoromethanesulfonic, nanofluorobutanesulfonic, perfluorosulfonic, pentafluorophosphoric, pentafluoroarsenic, pentafluoroantomonic, cyclo-1,3-perfluopropane disulfonyl imide, etc.) salts of diaryl iodonium, triaryl sulfonium, diaryl iodonium, and mixtures thereof.

An acid quencher or scavenger is a bulky weak base used to control diffusion of the photoacid, and typical examples are diethanol amine, triethanol amine, etc. The concentration of acid quencher is usually a small fraction of the equivalent of the photoacid generator. Alcoholic amines are generally preferred in the current patent because they can easily be immobilized by forming alkoxysilane bonds.

A flow control agent is a minor component (surfactant) used to reduce surface tension and minimize coating defects, and typical examples are fluorosilicones such as FMC 4430, FMC 4434 supplied by 3M of Maplewood, Minn.

The solvents or co-solvent of the composition include esters, ethers, glycol ethers esters, ketones, lactones, cyclic ketones, and mixtures thereof. Examples of solvents for the coating composition include amyl acetate, isobutyl isobutyrate, pentyl propionate, propylene glycol methyl ethyl acetate, cyclohexanone, 2-heptanone, ethyl 3-ethxoy-propionate, ethyl lactate, 3-valerolactone, methyl 3-methoxypropionate, and mixture thereof. The solvent is typically present in an amount of about 40 to 99 wt %, preferably in 30 to 95 wt %.

The photo patternable coating compositions of silicones and organic-inorganic hybrids can be coated on the substrate using techniques well known to those skilled in the art, such as dipping, spin-casting, roll, doctor-bladding, or spray. Depending on the applications, the film thickness of silicones or organic-inorganic hybrids can be controlled to 5 nm to 5 μm through the spin rate (dip rate if by dip coating) and the solids level. The coating can be dried at a temperature of 80-120° C. or below decomposition temperature of the photo acid generator in an oven or a hot plate or other known heating methods for a time between 30 seconds to several minutes to remove any residual solvents. Depending on the formulations, it can be photo-exposed using mercury I line, DUV wideband, KrF 248 nm, or ArF 193 nm printers or steppers and a photomask of the required pattern, and then post baked at 100-160° C. for 30-240 seconds to decompose the acid labile alkoxy groups and induce the silanol self condensation. Finally, the post baked coating is developed using an organic solvent to display a pattern which is a negative image of the photomask.

The developer may be selected according to the nature of the resin of silicon or organic-inorganic hybrid. The preferred developer includes esters, ethers, glycol ethers esters, ketones, lactones, cyclic ketones, and mixtures thereof. Examples of solvents for the coating composition include amyl acetate, isobutyl isobutyrate, pentyl propionate, propylene glycol methyl ethyl acetate, cyclohexanone, 2-heptanone, ethyl 3-ethxoy-propionate, ethyl lactate, 3-valerolactone, methyl 3-methoxypropionate, and mixture thereof.

Depending on the applications, post development vulcanization may be required to further promote silanol-silanol condensation. This can be either done by simply baking at a temperature of 150-220° C. To further increase the extent of vulcanization, the developed pattern may be treated with a catalyst solution for 30-60 seconds and then baked at a temperature of 150-220° C. A preferred catalyst is a dilute solution of salt of quaternary ammonium, quaternary phosphonium, or sulfonium with chloride, bromide, carbonate, carboxylates, etc. A very dilute solution of a strong organic strong base may also be used as long as it does not apparently dissolve the generated pattern.

Since the properties of the silicones or organic-inorganic hybrids described in the present invention may be tailored using multi-alkoxysilyl functional organics/polymers, these materials can be used as structural layers or non-sacrificial layers in IC, MEMS, and microfluidics applications. One of the unique features of the current invention is to prepare thin films with very high silicon contents (30-43 wt %). Since high silicon content films have excellent resistance to oxygen plasma etch, the photo patternable coating compositions of the present invention may be used as sacrificial layers for applications such as photoresist/hard mask (in BILAYER process), etch stopper, bottom anti-reflection coating/etch mask (in TRILAYER process), etc. The bottom anti-reflection coatings are well known as BARC to those with skills in the art. It is widely used in advanced photolithography to control interference due to reflections from the interfaces underneath in order to improve lithography resolution.

### EXAMPLES

Unless otherwise indicated, all numbers expressing quantities of ingredients, properties such as molecular weight, reaction conditions, and so forth used in the specification and claims are to be understood as being modified in all instances by the term “about”. Each of the documents referred to above are incorporated herein by reference in its entirety. For all purposes, the following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### Example 1

### t-Butoxy-diacetoxymethylsilane

t-Butoxy-diacetoxymethylsilane is a starting material for poly(t-butoxymethylsiloxane) and its copolymers. It is not commercially available, but can easily be prepared according to the following procedures as a mixture of methyltriacetoxysilane, methyl-t-butoxy-diacetoxysilane, and methyl-di-t-butoxy-acetoxysilane.

Commercial methyltriacetoxysilane (Gelest, 95 wt %) was sometimes brownish and must be vacuum-distilled so a colorless liquid was obtained. In a 1 liter one-neck round bottom flask were added 102.2 g (0.464 mole) of freshly distilled methyltriacetoxysilane and 34.4 g (0.464 mole) of t-butanol and heated at 80° C. for 4 hrs. Then the resulting acetic acid was removed by vacuum distillation with a Rotavapor. ¹HNMR showed the product is a mixture of 15.5% methyltriacetoxysilane, 71.6% of methyl-t-butoxy-diacetoxysilane, and 13.2% of methyl-dibutoxy-acetoxysilane.

### Example 2

### Poly(t-butoxymethylsiloxane)

### Resin 1

Resin 1 as prepared in this example may not be linear as the above chemical name suggested. It is more likely a branch, cyclic, polycyclic, polyhedral, or a mixture/combination thereof defined by a siloxane skeleton of [OSi(CH₃)(O-t-Bu)]ₘ[O_{1.5}Si(CH₃)]ₙ[OSi(CH₃)(OH)]ₚ with pendant groups of [—O_{0.5}Si(CH₃)(O-t-Bu)₂], [—O_{0.5}Si(CH₃)(O-t-Bu)(OH)], and small amount of [O_{0.5}Si(CH₃)(OH)₂]. After deblocking all the t-butoxy group and full silanol condensation, the resin converts to a siloxane resin named as poly(methylsilsesquioxane) or [—Si(CH₃)O_{3/2}—].

In a 1 liter one-neck round bottom flask were added 128 g of t-butanol and 22.0 g (0.094 mole) of t-butoxydiacetoxymethylsilane (Example 1). While being stirred, 2.11 g (0.117 mole) of deionized water were added to hydrolyze the acetoxy groups, and 0.10 g of 0.1 N HCl aqueous solution was added as a catalyst. The mixture was refluxed for about 8 hrs, 50.0 g of propylene glycol methyl ether acetate (PGMEA) were added. The mixture was vacuum-distilled until almost dry to remove most of t-butanol, acetic acid, and PGMEA. Another 50.0 g of PGMEA were added again and the mixture was vacuum-distilled until almost dry again. The remainder was diluted to a solution of PGMEA with a solid level of about 15 wt %. GPC result showed an Mₙ of 1400 and an M_{w} of 12000. GC showed the solvent included about 0.5-1% of acetic acid and 2-3% of t-butanol. NMR indicated the stoichoimetry of t-butoxy was significantly lower than the theoretic value (60-75%), indicating some of the t-butoxy groups were lost during the reaction.

### Example 3

### Poly(methylsilsesquioxane 50-co-dibutoxysiloxane 50)

### Resin 2

Resin 2 as prepared in this example may not be as simple as the above chemical name suggests, it is so called only for purpose of simplicity. After deblocking all the t-butoxy group and full silanol condensation, the resin converts to a siloxane resin named as poly(methylsilsesquioxane-co-orthosilicate) or [—Si(CH₃)O₃/2-co-SiO_{4/2}—].

In a 1 liter one-neck round bottom flask were added 128 g of tetrahydrofuran, 12.89 g (0.0585 mole) of vacuum distilled methyltriacetoxysilane [Gelest], and 17.11 g (0.0585 mole) of dibutoxy-diacetoxysilane [Gelest, 96 wt %, colorless liquid, used as received]. While being stirred, 3.29 g (0.183 mole) of deionized water were added to hydrolyze the acetoxy groups, and 0.1 g of 0.1 N HCl aqueous solution was added as a catalyst. The mixture was refluxed for about 8 hrs, 50.0 g of propylene glycol methyl ether acetate (PGMEA) were added. Then mixture was vacuum-distilled to almost dry to remove most of t-butanol, acetic acid, and PGMEA. Another 50.0 g of PGMEA were added again and the mixture was vacuum distilled to almost dry again. Finally, the remainder was diluted using PGMEA to a solids level of 15 wt %. GPC results showed an Mₙ of 3400 and an M_{w} of 19000. GC showed the solvent included about 1 wt % of acetic acid and 2-3 wt % of t-butanol. NMR indicated the stoichoimetry of t-butoxy was significantly lower than the theoretic value (40%-60%) indicating some of the t-butoxy groups were lost during the reaction.

### Example 4

### Poly(methylsilsesquioxane 50-co-dibutoxysiloxane 50)

### Resin 3

This resin is stoichiometrically similar to the one in Example 3, but was prepared using a base catalyst. After deblocking all the t-butoxy group and full silanol condensation, the resin converts to a siloxane resin named as poly(methylsilsesquioxane-co-orthosilicate) or [—Si(CH₃)O_{3/2}-co-SiO_{4/2}—]

In a 1 liter one-neck round bottom flask were added 128 g of tetrahydrofuran, 12.89 g (0.0585 mole) of vacuum distilled methyltriacetoxysilane [Example 1], and 17.11 g (0.0585 mole) of di-butoxy-diacetoxysilane [Gelest]. While the mixture was stirred rigorously using a mechanical stirrer at 40° C., 16.87 g (0.176 mole) of anhydrous ammonium carbonate (99.0%, Aldrich) were added in parts over a period of 30 minutes. After adding all the ammonium carbonate, the mixture was stirred at 40° C. for another 6 hrs. The resulting ammoniums acetate salt was filtered from the solution; the resin was recovered from the filtrate by vacuum distillation (until almost dry). The resin was re-dissolved in tetrahydrofuran and filtered again to remove residual ammonium acetate salt. About 0.1 g of triethylamine was added to the acetate solution as the catalyst and refluxed for 6 hrs to ensure full silanol condensation. Then the solvent and catalyst were vacuum-stripped. Finally, the polymer was dissolved in PGMEA as a solution with 15% solids. By this procedure, obtained was a new polymer whose structure was more closely represented by the name poly(silsesquioxane-co-dibutoxysiloxane). NMR indicated this resin had a significantly higher level of t-butoxy groups (75-90% of theoretical value).

### Example 5

### Resin 4

Resin 4 is not formally named because of its complicated molecular structure. After deblocking all the t-butoxy group and full silanol condensation, Resin 5 converts to an organic-inorganic hybrid chemically represented by [—O_{3/2}Si—CH₂CH₂—SiO_{3/2}—].

In a 1 liter round bottom flask were added 150.0 g of tetrahydrofuran and 22.0 g (0.0741 mole) of 1,2-bis(trichlorosilyl)ethane (Gelest). While the mixture was stirred, 10.68 g (0.111 mole) of ammonium carbonate were added slowly. After adding all the ammonium carbonate, the mixture was kept stirred at 40° C. for 2 more hrs. While the mixture was cooled with cold water, 26.36 g (0.356 mole) of t-butanol were added to convert the remaining Si—Cl groups to Si—(O-t-Bu) groups, the hydrochloric acid generated was neutralized by about 22.5 g (0.222 mole) of triethylamine. The mixture was stirred for 4 hrs, the resulting ammonium chloride and triethylammonium chloride were filtered and rinsed with tetrahydrofuran. The resin solution was refluxed for 4 hrs to allow full silanol-silanol condensation. 50 g of PGMEA were added and the mixture was vacuum distilled to almost dry to remove t-butanol and residual triethylamine. Another 50 g of PGMEA were added to polymer. The solution was filtered and the solvent was stripped again. Finally, enough PGMEA was added to prepare a 15% solids solution of Resin 4.

### Example 6

### Resin 5

Resin 5 is not formally named because of its complicated molecular structure. After deblocking all the t-butoxy group and full silanol condensation, the resin converts to an organic-inorganic hybrid chemically represented by [—O_{3/2}Si—(CH₂)₆—SiO_{3/2}—].

In a 1 liter round bottom flask were added 150.0 g of tetrahydrofuran and 22.0 g (0.0623 mole) of 1,6-bis(trichlorosilyl)hexane. While the mixture was stirred, 8.98 g (0.0934 mole) of ammonium carbonate were added slowly. After adding all the ammonium carbonate, the mixture was kept stirred at 40° C. for 2 more hrs. While the mixture was cooled with cold water, 22.17 g (0.299 mole) of t-butanol were added to convert the remaining Si—Cl groups to Si—(O-t-Bu) groups, the hydrochloric acid generated was neutralized by 18.92 g (0.187 mole) of triethylamine. The mixture was stirred for 4 hrs, the resulting ammonium chloride and triethylammonium chloride were filtered using a Buchi funnel and the salts were rinsed with tetrahydrofuran. The resin solution was refluxed for 4 hrs to allow silanol-silanol condensation. 50 g of PGMEA were added and the mixture was vacuum distilled to almost dry to remove t-butanol and residual triethylamine. Then another 50 g of PGMEA were added again and evaporated by vacuum distillation. Finally, the resin was diluted with PGMEA to obtain a solution with a solids level of 15%.

### Example 7

### Resin 6

Resin 6 is not formally named because of its complicated network structure. After deblocking all the t-butoxy group and full silanol condensation, the resin converts to an organic-inorganic hybrid chemically represented by [Si(CH₃)₂O_{2/2}-co-O_{3/2}Si—(CH₂)₆—SiO_{3/2}—].

In a 1 liter round bottom flask were added 150.0 g of tetrahydrofuran, 22.0 g (0.0623 mole) of 1,6-bis(trichlorosilyl)hexane, and 5.0 g (0.0387 mole) of dimethyldichlorosilane. While the mixture was stirred, 12.70 g (0.132 mole) of ammonium carbonate were added slowly. After adding all the ammonium carbonate, the mixture was kept stirred at 40° C. for 2 more hrs. While the mixture was cooled with cold water, 25.09 g (0.212 mole) of t-butanol were added to convert the remaining Si—Cl groups to Si—(O-t-Bu) groups, the hydrochloric acid generated was neutralized by 21.41 g (0.211 mole) of triethylamine. The mixture was stirred for 4 hrs, the resulting ammonium chloride and triethylammonium chloride were filtered using a Buchi funnel and the salts were rinsed with tetrahydrofuran. The resin solution was refluxed for 4 hrs to allow silanol-silanol condensation. 50 g of PGMEA were added and the mixture was vacuum distilled to almost dry to remove t-butanol and residual triethylamine. Then another 50 g of PGMEA were added again and evaporated by vacuum distillation. Finally, the resin was diluted with PGMEA to obtain a solution with a solids level of 15%.

### Example 8

This example provides several reference formulations for DUV photo patternable silicones and/or organic-inorganic hybrids using resins prepared in Examples 2-7. In Table 1, Resins 1-6 are the resins synthesized in Examples 2-7. Formulations #1-6 are based on a major resin of silicones (siloxane) or organic-inorganic hybrids which contain acid labile groups (—O-t-Bu); while Formulation #7 is based on two major components: a poly(t-butoxymethylsiloxane) and a star silane. It should be noted that formulation of photo patternable coatings are dependent on the radiation used for photo patterning. It is generally required that the major components are transparent to the radiation; However, the photo acid generator (PAG) should be able to absorb radiation. Otherwise, a photo sensitizer has to be used to transfer energy to the photo acid generator. The strategies to formulate these photo imagable compositions are well known to those with skills in the arts.

TABLE 1
Reference formulations for DUV photo patternable silicones or organic-inorganic hybrids

| | Formulations | | | | | | |
|---|---|---|---|---|---|---|---|
| Components | #1 | #2 | #3 | #4 | #5 | #6 | #7 |
| Resin 1 (15%) | 6.67 | — | — | — | — | — | 6.67 |
| Resin 2 (15%) | — | 6.67 | — | — | — | — | — |
| Resin 3 (15%) | — | — | 6.67 | — | — | — | — |
| Resin 4 (15%) | — | — | — | 6.67 | — | — | — |
| Resin 5 (15%) | — | — | — | — | 6.67 | — | — |
| Resin 6 (15%) | — | — | — | — | — | 6.67 | — |
| 3-Trimethoxysilylpropyl- | — | — | — | — | — | — | 1 |
| isocyanurate | | | | | | | |
| Triphenylsulfonium | 0.01-0.02 | 0.01-0.02 | 0.01-0.02 | 0.01-0.02 | 0.01-0.02 | 0.01-0.02 | 0.01-0.02 |
| perfluorobutane | | | | | | | |
| sulfonate | | | | | | | |
| Triethyanolamine | 0.0002- 0.0004 | 0.0002-0.0004 | 0.0002-0.0004 | 0.0002-0.0004 | 0.0002-0.0004 | 0.0002-0.0004 | 0.0002-0.0004 |
| FMC 4434 | ~0.001 | ~0.001 | ~0.001 | ~0.001 | ~0.001 | ~0.001 | ~0.001 |
| Isobutyl isobutyrate | 70 | 70 | 70 | 70 | 70 | 70 | 70 |
| PGMEA | 23.3 | 23.3 | 23.3 | 23.3 | 23.3 | 23.3 | 23.3 |

### Example 9

This example provides a reference procedure for processing a UV patternable composition of silicones or organic-inorganic hybrids. Formulations #1-7 were spin-cast on a wafer of silicon as a film, the prebaked at about 90° C. to remove solvents. The coating was exposed using a DUV lithography tool (e.g. contact printing, proximity printing, or projection printing), post-baked at about 120-160° C. to deblock the acid labile group and promote subsequent silanol condensation, and finally developed using an organic solvent such as isobutyl isobutyrate or PGMEA. Patterns of silicones or organic-inorganic hybrids prepared this way often contain considerable amount of free silanol groups. For some applications, especially as non-sacrificial layers, post curing at a higher temperature (160-220° C.) may be required to eliminate silanol residuals. Pretreating the pattern with a dilute solution (0.1%) of a quaternary ammonium, quaternary phosphonium, sulfonium salt of chloride, bromide, carbonate, or carboxylates before post curing was proven to be very effective in increasing the degree of curing at the same curing temperature.

I claim:

1. A negative-tone photo patternable coating composition containing: (1) at least one silicone or organic-inorganic hybrid resin with acid labile groups; (2) Optionally, a multi-alkoxysilyl functional organic/polymer; (3) a photoacid generator; (4) an acid quencher; (5) a flow control agent; and (6) at least one organic solvent.

2. The silicone or organic-inorganic hybrid resin in claim 1 is defined as networks comprised of the following silicon tetrahedral structural units 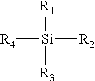
where
R₁, R₂, R₃, R₄ are the four substituents of the silicon central atom, and they are selected from the five classes of groups Rₐ, R_{b}, R_{c}, and R_{d} and Rₑ.
Rₐ, R_{b}, R_{c}, R_{d}, and Rₑ are radicals containing no basic functional groups (pK_{b}<12) so photoacid generatored won't be neutralized. Therefore, radicals containing basic groups such as amine, pyridine, imine, guanidine, etc. much be excluded from the lists of Rₐ, R_{b}, R_{c}, R_{d}, and Rₑ.
Rₐ is defined as mono alkyl (hydrogen, alkyl, aryl, aralkyl) radical with 0-12 carbons, however, with 1-6 carbons preferred. It is a pendant group not linking to other silicon tetrahedrons. It can be linear, branched, or cyclic/polycyclic in structure. Examples are methyl, ethyl, propyl, 2-propyl, n-butyl, 2-butyl, t-butyl, phenyl, o, m, p-methylphenyl, etc. Oxygen, nitrogen, sulfur, or phosphor atoms may be included in a mono radical R group, but no basic groups should exist. Examples are 2-cyanopropyl, 3-cyanopropyl, 3-methoxypropyl, 3-(methoxycarbonyl)ethyl, 3-mercaptanpropyl, etc.
R_{b} is defined as organic diradicals or multi-radicals, which are linked to two or more silicon tetrahedrons. R₂ may be selected from hydrocarbons or organics containing oxygen, nitrogen, sulfur, or phosphor atoms, but should not include basic functional groups. A simple di-radical R group can be, but not limited to —[CH₂]ₙ—, n=1-10, 1,4-phenylene, 1,3-phenylene, 1,2-phenylene, 1,4-cyclohexylene, 1,3-cyclohexylene, 1,2-cyclohexylene, polyethyl glycols, or Polypropylene glycols. A simple multi-radical R group can be, but not limited to 1,3,5-Ph≡, 1,2,4-Ph≡, 1,2,3-Ph≡, —CH₂CH(−)CH₂—, ≡C═CHCH₂—, etc.
R_{c} is defined as -OL group, where L is an acid labile group. It includes but not limited to t-butoxy, t-pentoxy (2-methyl-2-butoxy), 1-phenyl-1-ethoxy, 2-phenyl-2-propoxy, and similar species; Due to its small volume, t-butoxy group is the most preferred if a dense film is required.
R_{d} is defined as —OR group, where R is a mono radical similar to R_{c} defined earlier, but not acid labile (e.g. typically hydrogen, methyl, ethyl, or propyl, isopropyl).
Rₑ is defined as —OSi group, which represents a siloxane linkage (Si—O—Si).
R₁, R₂, R₃ and R₄ must contain at least one R_{b} or Rₑ so the silicon tetrahedral unit is a part of a network. R₁, R₂, R₃ and R₄ may contain 0-2 Rₐs (typically 0 or 1), and 0-3 R_{c}s.
For photo patternable composition applications, none of Rₐ, R_{b}, R_{c}, R_{d}, and Rₑ contain any light absorbing chromophores at the wavelength of photolithography so that the resulting resin of silicone or organic-inorganic hybrid transparent. For 365 nm and 248 nm photolithography, none of Rₐ, R_{b}, R_{c}, R_{d}, and Rₑ can include any fused aromatic radicals due to the high absorption. For 193 nm photolithography, even benzene ring cannot be incorporated in Rₐ, R_{b}, R_{c}, R_{d}, and Rₑ.

3. The organic-inorganic hybrid network in claim 2 can be further expressed by the following structure 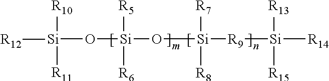
where
m and n are number of duplication.
R₅ and R₆, R₇, R₈, and R₉ in each duplication unit may not be the same.
R₅ and R₆ are selected from Rₐ, R_{b}, R_{c}, R_{d}, and Rₑ. If R₅ and R₆ are selected from Rₐ, R_{c}, and R_{d} only, the silicon tetrahedral unit is a chain extension unit. If either or both of R₅ and R₆ are R_{b} or Rₑ, the silicon tetrahedral unit is a network joint.
R₇ and R₈ are selected from Rₐ, R_{b}, R_{c}, R_{d}, and Rₑ, and R₉ is a R_{b}. If R₇ and R₈ are Rₐ, R_{c}, and R_{d}, and R₉ is a diradical R_{b}, the silicon tetrahedral unit is a chain extension unit. Otherwise, the silicon tetrahedral unit is a network joint.
R₁₀, R₁₁, R₁₂, R₁₃, R₁₄, R₁₅ are selected from Rₐ, R_{c}, R_{d}, the silicon tetrahedrons they attached to are pendant groups.
The network joints of the polymer must be limited so that the silicone or organic-inorganic hybrid resin remain soluble.
A large percentage (10-100%, 25-75% preferred) of R₅-R₈ and R₁₀-R₁₅ must be R_{c}, the acid labile alkoxy group.

4. A silicone or organic-inorganic hybrid resin in claim 3 is poly(t-butoxymethylsiloxane), poly(t-butoxyphenylsiloxane), poly(t-butoxyvinylsiloxane), poly(t-butoxymethylsiloxane-co-di-t-butoxysiloxane), poly(t-butoxymethylsiloxane-co-oxy(di-t-butoxysilylene-ethylene-di-t-butoxysiloxane), poly(t-butoxymethylsiloxane-co-oxy(di-t-butoxysilylene-hexylene-di-t-butoxysiloxane), poly(dimethylsiloxane-co-oxy(di-t-butoxysilylene-hexylene-di-t-butoxysiloxane), etc.

5. If poly(di-t-butoxysiloxane) is the only silicone used in claim 1 that has acid labile groups, the optional component multi alkoxysilyl functional organic/polymer additive is necessary.

6. The photo acid generator in claim 1 is selected from onium salts of super acids, sulfonate compounds, nitrobenzyl esters, triazines, etc. Examples of preferred photo acid generators include but are not limited to onium salts of sulfonates, perfluoroalkylsulfonate, perfluoroalkyldisulfonyl imides, especially those of diphenyl iodium salts, triphenyl sulfonium salts, dialkyl iodonium salts, trialkylsulfonium salts, and mixtures thereof.

7. The acid quencher or scavenger in claim 1 is a nonvolatile amine, for example, diethanol amine, triethanol amine, etc. Alcoholic amines are generally preferred in the current patent because they can easily be immobilized by forming alkoxysilane bonds.

8. The flow control agent in claim 1 is a minor component (surfactant) used to reduce surface tension and minimize coating defects, and typical examples are fluorosilicones such as FMC 4430, FMC 4434, etc.

9. The solvents or co-solvent of the composition in claim 1 include esters, ethers, glycol ethers esters, ketones, lactones, cyclic ketones, and mixtures thereof. Examples of solvents for the coating composition include amyl acetate, isobutyl isobutyrate, pentyl propionate, propylene glycol methyl ethyl acetate, cyclohexanone, 2-heptanone, ethyl 3-ethxoy-propionate, ethyl lactate, gamma valerolactone, methyl 3-methoxypropionate, and mixture thereof. The solvent is typically present in an amount of about 40 to 99 wt %, preferably in 30 to 95 wt %.

10. The photo patternable compositions in claim 1 are processed by a process including film casting, prebaking at 80-100° C., UV exposure, postbaking at 100-160° C., development with organic solvents, and optionally soaking with a salt of quaternary ammonium quaternary phosphonium, trialkyl sulfonium with chloride, bromide, and carboxylates, followed by post curing at 160-220° C.
